(19) United States
(12) Patent Application Publication
(10) Pub. No.: US 2015/0114559 A1
(43) Pub. Date: Apr. 30, 2015

(54) PLASMA SHIELDING MEMBERS, PLASMA DETECTING STRUCTURES, AND PLASMA REACTION APPARATUSES

(71) Applicants: Eun-Young HAN, Hwaseong-si (KR); Hyun-Su JUN, Hwaseong-si (KR); Gyung-jin MIN, Seongnam-si (KR); Kye-Hyun BAEK, Suwon-si (KR); Tae-Rang KIM, Ansan-si (KR)

(72) Inventors: Eun-Young HAN, Hwaseong-si (KR); Hyun-Su JUN, Hwaseong-si (KR); Gyung-jin MIN, Seongnam-si (KR); Kye-Hyun BAEK, Suwon-si (KR); Tae-Rang KIM, Ansan-si (KR)

(21) Appl. No.: 14/461,651

(22) Filed: Aug. 18, 2014

(30) Foreign Application Priority Data
Oct. 30, 2013 (KR) 10-2013-0130444

(51) Int. Cl. C23F 1/02; C23C 16/04; C23F 1/08; H01J 37/32

(52) U.S. Cl. CPC C23F 1/02; H01J 37/32798; C23C 16/042; C23F 1/08
USPC 156/345.3; 118/504

(57) ABSTRACT

A plasma shielding member may include a body having a first surface and a second surface that are opposite to each other, and a plurality of through holes each extending from the first surface to the second surface; a narrower portion of a respective through hole formed at one end of each of the through holes; and/or a wider portion of the respective through hole formed at another end of each of the through holes. A plasma shielding member may include a body including a plurality of through holes that extends from a first surface of the body toward a second surface of the body. Each of the through holes may be defined by a narrower portion of the body at a first end of the respective through hole, and by a wider portion of the body at a second end of the respective through hole.

### CROSS-REFERENCE TO RELATED APPLICATION(S)

This application claims priority from Korean Patent Application No. 10-2013-0130444, filed on Oct. 30, 2013, in the Korean Intellectual Property Office (KIPO), the disclosure of which is incorporated herein in its entirety by reference.

### BACKGROUND

1. Field

Some example embodiments of the inventive concepts may relate to plasma shielding members, structures for detecting plasma, and/or plasma reaction apparatuses. Some example embodiments of the inventive concepts may relate to plasma shielding members having a plurality of through holes, structures for detecting plasma, and/or plasma reaction apparatuses.

2. Description of Related Art

When manufacturing semiconductor devices, a plasma reaction apparatus using plasma may be used in an etching process or a deposition process. Such a plasma reaction apparatus may perform a process monitoring operation or an end point detection (EPD) operation by analyzing a plasma beam.

In order to perform the process monitoring operation or the EPD operation, a plasma beam may be detected outside of the plasma reaction apparatus. However, a detection member may be contaminated or damaged by the plasma beam and, accordingly, an error may occur in the process monitoring operation or the EPD operation.

### SUMMARY

Some example embodiments of the inventive concepts may provide plasma shielding members capable of preventing contamination and/or damage to detection members for detecting plasma beams. Some example embodiments of the inventive concepts may provide structures for detecting plasma. Some example embodiments of the inventive concepts may provide plasma reaction apparatuses.

In some example embodiments, a plasma shielding member may comprise: a body having a first surface and a second surface that are opposite to each other, and a plurality of through holes each extending from the first surface to the second surface; a narrower portion of a respective through hole formed at one end of each of the plurality of through holes; and/or a wider portion of the respective through hole formed at another end of each of the plurality of through holes.

In some example embodiments, the narrower portion of the respective through hole may be formed in the first surface of the body. The second surface of the body may be configured to receive a light transmission member that transmits plasma beams passed through the plurality of through holes.

In some example embodiments, each of the plurality of through holes may extend from the narrower portion of the respective through hole to the wider portion of the respective through hole while forming an inclined surface.

In some example embodiments, each of the plurality of through holes may have a cross-section which, when seen from a side surface of the respective through hole, forms an inclined surface straight from the narrower portion of the respective through hole to the wider portion of the respective through hole.

In some example embodiments, each of the plurality of through holes may have a cross-section which, when seen from a side surface of the respective through hole, forms an inclined surface curved from the narrower portion of the respective through hole to the wider portion of the respective through hole.

In some example embodiments, each of the plurality of through holes may extend from the narrower portion of the respective through hole to the wider portion of the respective through hole while forming a concavely inclined surface or a convexly inclined surface.

In some example embodiments, each of the plurality of through holes may have a cross-section which, when seen from the first surface or the second surface, has a circular shape, a polygonal shape, or a combined shape of the circular and polygonal shapes.

In some example embodiments, the body may include a recessed space that is depressed from the second surface. The recessed space may be connected to the plurality of through holes.

In some example embodiments, the plurality of through holes may be arranged in zig-zags with respect to a direction on a plane that is parallel to the first surface.

In some example embodiments, a mixture space, in which plasma beams transmitted through at least two adjacent through holes among the plurality of through holes are mixed, may be formed to be adjacent to the wider portions of the at least two adjacent through holes.

In some example embodiments, the body may have an etch stop layer on the first surface.

In some example embodiments, the etch stop layer may comprise Y₂O₃, Sc₂O₃, SC₂F₃, YF₃, La₂O₃, CeO₂, EU₂O₃, Or DyO₃.

In some example embodiments, the body may have an anti-oxidation layer on the second surface.

In some example embodiments, a plasma detecting structure may comprise: a plasma shielding member having a first surface and a second surface that are opposite to each other, a plurality of first through hole portions each extending from the first surface to the second surface, and a second through hole portion extending from the second surface toward the first surface to be connected to the plurality of first through hole portions; and/or a light transmission member comprising a boundary portion contacting the second surface of the plasma shielding member, and an intermediate portion separated from the plasma shielding member by a space that is defined by the second through hole portion, and is interposed between the plasma shielding member and the intermediate portion.

In some example embodiments, the plurality of first through hole portions may extend so that cross-sectional areas of spaces defined by the first through hole portions increase from the first surface toward the second surface.

In some example embodiments, the plurality of first through hole portions may extend so that the cross-sectional areas of the spaces defined by the first through hole portions increase linearly from the first surface toward the second surface.

In some example embodiments, the plurality of first through hole portions may extend so that the cross-sectional areas of the spaces defined by the first through hole portions increase non-linearly from the first surface toward the second surface.

In some example embodiments, a plasma reaction apparatus may comprise: a chamber including an opening; a plasma shielding member comprising a first surface and a second surface that are opposite to each other and a plurality of through holes each extending from the first surface to the second surface, wherein the plasma shielding member is mounted in the opening so that the first surface faces the chamber; and/or a light transmission member coupled to the second surface of the plasma shielding member.

In some example embodiments, the plasma shielding member may be mounted in the opening so that the first surface protrudes to an inside of the chamber.

In some example embodiments, a mixture space, in which plasma beams transmitted through at least two adjacent through holes among the plurality of through holes are mixed, may be formed between the plasma shielding member and the light transmission member.

In some example embodiments, a plasma reaction apparatus may comprise: a chamber including an opening; a body mounted in the opening and including a plurality of through holes; a narrower portion of a respective through hole formed at one side of each of the plurality of through holes, wherein the narrower portions of the plurality of through holes are at a chamber side; a wider portion of the respective through hole formed at another side of each of the plurality of through holes, wherein the wider portions of the plurality of through holes are opposite to the chamber side; a light transmission member separated from the wider portions of the plurality of through holes and coupled to the body; and/or an optical emission spectrometer attached adjacent to the light transmission member, and configured to analyze plasma beams transmitted through the plurality of through holes from the chamber.

In some example embodiments, the chamber may be a dry etching chamber or a chemical vapor deposition chamber.

In some example embodiments, the optical emission spectrometer may be configured to sense an etch stop point or generation of particles.

In some example embodiments, cross-sectional areas of the plurality of through holes may increase from the narrower portions of the plurality of through holes to the wider portions of the plurality of through holes.

In some example embodiments, a plasma shielding member may comprise: a body including a plurality of through holes that extends from a first surface of the body toward a second surface of the body. Each of the plurality of through holes may be defined by a narrower portion of the body at a first end of the respective through hole, and by a wider portion of the body at a second end of the respective through hole.

In some example embodiments, each of the plurality of through holes may extend from the narrower portion of the body to the wider portion of the body while forming a straight inclined surface.

In some example embodiments, each of the plurality of through holes may extend from the narrower portion of the body to the wider portion of the body while forming a curved inclined surface.

In some example embodiments, the body may include a recessed space that extends from the plurality of through holes to the second surface of the body.

In some example embodiments, a mixture space, in which plasma beams transmitted through at least two adjacent through holes among the plurality of through holes are mixed, may be formed adjacent to respective wider portions of the body.

In some example embodiments, a mixture space, in which plasma beams transmitted through at least two adjacent through holes among the plurality of through holes are mixed, may be formed between respective wider portions of the body and the second surface of the body.

### BRIEF DESCRIPTION OF THE DRAWINGS

The above and/or other aspects and advantages will become more apparent and more readily appreciated from the following detailed description of example embodiments, taken in conjunction with the accompanying drawings, in which:

FIGS. 1A and 1B are diagrams of a plasma reaction apparatus according to some example embodiments of the present inventive concepts;

FIGS. 2A and 2B are cross-sectional views of a structure for detecting plasma mounted in a chamber, according to some example embodiments of the present inventive concepts;

FIGS. 3A through 3C are perspective views of a plasma shielding member and a light transmission member included in a structure for detecting plasma according to some example embodiments of the present inventive concepts;

FIGS. 4 through 6 are cross-sectional views enlarging some parts of a structure for detecting plasma according to some example embodiments of the present inventive concepts;

FIGS. 7A and 7B are cross-sectional views showing enlarged views of some parts of a plasma shielding member according to some example embodiments of the present inventive concepts;

FIGS. 8 through 11 are plan views showing enlarged views of some parts of the plasma shielding member according to some example embodiments of the present inventive concepts;

FIG. 12 is a cross-sectional view of a structure for detecting plasma according to some example embodiments of the present inventive concepts;

FIG. 13 is a perspective view of a plasma shielding member included in the structure for detecting plasma, according to some example embodiments of the present inventive concepts;

FIG. 14 is a cross-sectional view showing an enlarged view of a part of the structure for detecting plasma according to some example embodiments of the present inventive concepts;

FIGS. 15A and 15B are images of a light transmission member included in a general structure for detecting plasma;

FIGS. 16A and 16B are images of a light transmission member included in a structure for detecting plasma according to some example embodiments of the present inventive concepts; and

FIG. 17 is a graph showing plasma detecting efficiency of a plasma reaction apparatus using the structure for detecting plasma according to some example embodiments of the present inventive concepts.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof

Example embodiments may be described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will typically have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature, their shapes are not intended to illustrate the actual shape of a region of a device, and their shapes are not intended to limit the scope of the example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

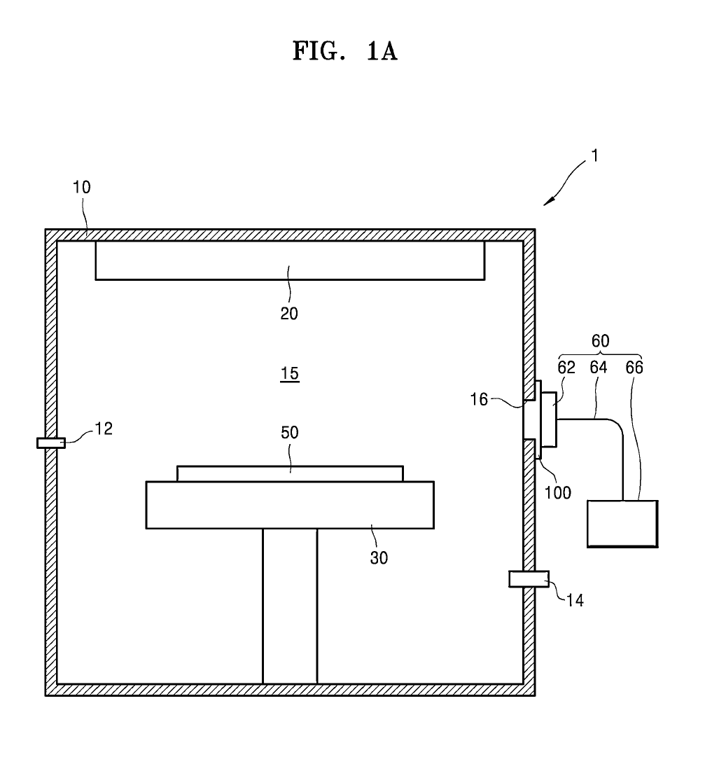

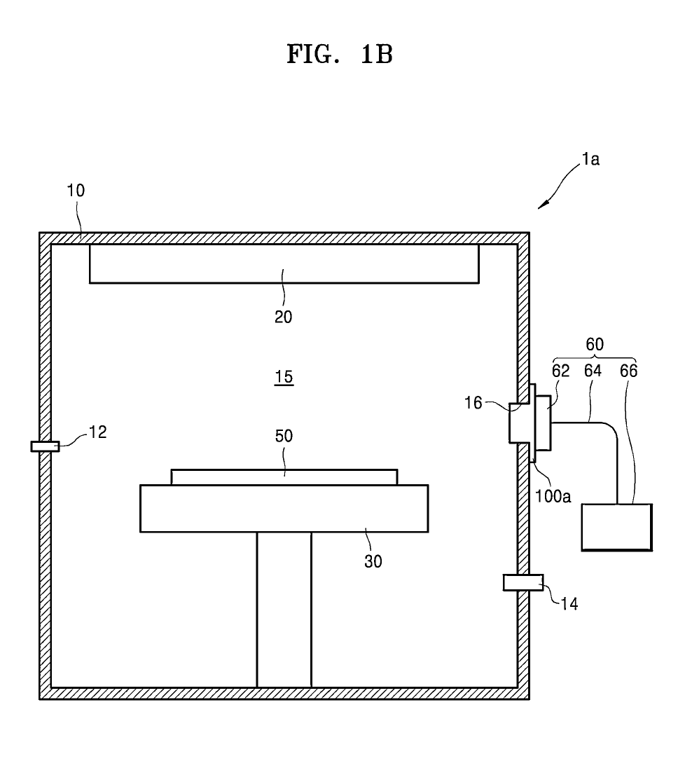

FIG. 1A is a block diagram of a plasma reaction apparatus 1 according to some example embodiments of the present inventive concepts.

Referring to FIG. 1A, the plasma reaction apparatus 1 includes an electrode plate 20 and a substrate holder 30 in a chamber 10. The chamber 10 may process, for example, a 200 millimeter (mm) substrate, a 300 mm substrate, or larger, and may help generation of plasma. A substrate 50 may be mounted on the substrate holder 30. The electrode plate 20 may function as an upper electrode of the plasma reaction apparatus 1, and may be coupled to a radio frequency (RF) source. The substrate holder 30 may be, for example, an electrostatic chuck. The substrate 50 may be attached to the substrate holder 30 via an electrostatic clamping system. The substrate holder 30 may include an electrode. Plasma may be generated in a plasma reaction space 15 between the electrode plate 20 and the substrate holder 30. An RF voltage may be electrically biased to the substrate holder 30, for example, via an impedance matching network. Such an RF bias voltage may accelerate electrons for generating and maintaining plasma. A frequency of the RF bias voltage may range from 1 megahertz (MHz) to 100 MHz, for example, 13.56 MHz.

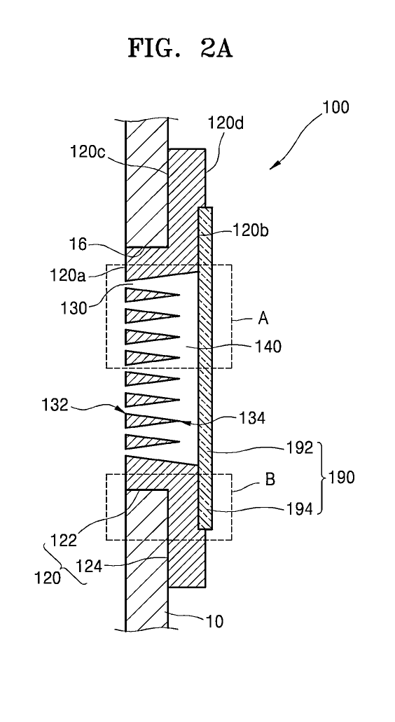

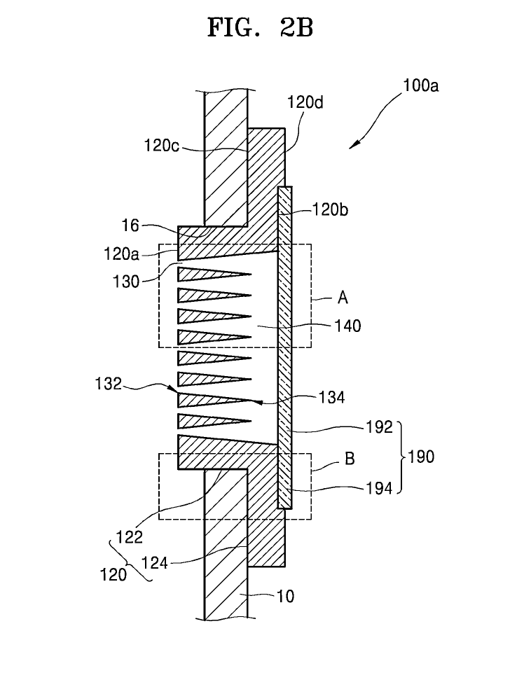

The chamber 10 includes an opening 16 to which a plasma detecting structure 100 may be mounted. The plasma detecting structure 100 will be described below with reference to FIGS. 2A through 14.

The chamber 10 may include at least one supply hole 12 and at least one exhaust hole 14. The at least one supply hole 12 may be for supplying a reaction gas or a purge gas into the chamber 10. The at least one exhaust hole 14 may exhaust air, gas, or by-products inside the chamber 10 to outside of the chamber, and a pump (not shown) may be connected to the exhaust hole 14, if necessary.

A spectrum analyzer 60 may be connected to the plasma detecting structure 100. The spectrum analyzer 60 may include a photocoupler 62, an optical cable 64, and an analyzer 66. The optical cable 64 is coupled to the plasma detecting structure 100 so that the plasma detecting structure 100 may transfer a plasma beam to the optical cable 64. The analyzer 66 may analyze a spectrum of the plasma beam that is transferred from the plasma detecting structure 100.

The plasma reaction apparatus 1 may be, for example, an etching apparatus or a deposition apparatus. The chamber 10 may be, for example, an etching chamber or a deposition chamber. The plasma reaction apparatus 1 may be, for example, a dry-etching apparatus or a chemical vapor deposition (CVD) apparatus. The chamber 10 may be, for example, a dry-etching chamber or a CVD chamber.

The spectrum analyzer 60 may analyze a plasma beam passing through the plasma detecting structure 100 from the chamber 10 of the plasma reaction apparatus 1. The spectrum analyzer 60 may detect an etch stop point by analyzing the plasma beam in a case where the plasma reaction apparatus 1 is an etching apparatus. The spectrum analyzer 60 may detect generation of particles by analyzing the plasma beam in a case where the plasma reaction apparatus 1 is a deposition apparatus.

When performing a dry-etching process by using plasma, an object layer located on an etch stop layer is removed until the etch stop layer is exposed or an object layer located on a lower layer is removed until the lower layer under the object layer is exposed. Therefore, when the etching of the object layer is finished, the etch stop layer is exposed so as not to proceed the etching operation further, or the lower layer formed of different material from that of the object layer is exposed so that the plasma beam generated by the plasma reaction apparatus 1 is changed. Therefore, the spectrum analyzer 60 detects such a change in the plasma beam, and may detect the etch stop point.

When a CVD process is performed by using plasma, particles, that is, undesired impurities, are generated, and then, the plasma beam generated by the plasma reaction apparatus 1 is changed. Thus, the spectrum analyzer 60 may detect the generation of particles by analyzing the change in the plasma beam.

FIG. 1B is a block diagram of a plasma reaction apparatus la according to some example embodiments of the present inventive concepts. Descriptions about components in the plasma reaction apparatus la, which are the same as those of FIG. 1A, are omitted here.

Referring to FIG. 1B, the plasma reaction apparatus la includes the electrode plate 20 and the substrate holder 30 in the chamber 10. The chamber 10 includes the opening 16, and a plasma detecting structure 100a may be mounted on the opening 16.

Unlike the plasma detecting structure 100 shown in FIG. 1A, the plasma detecting structure 100a of FIG. 1B may be mounted in the opening 16 so as to protrude into the chamber 10.

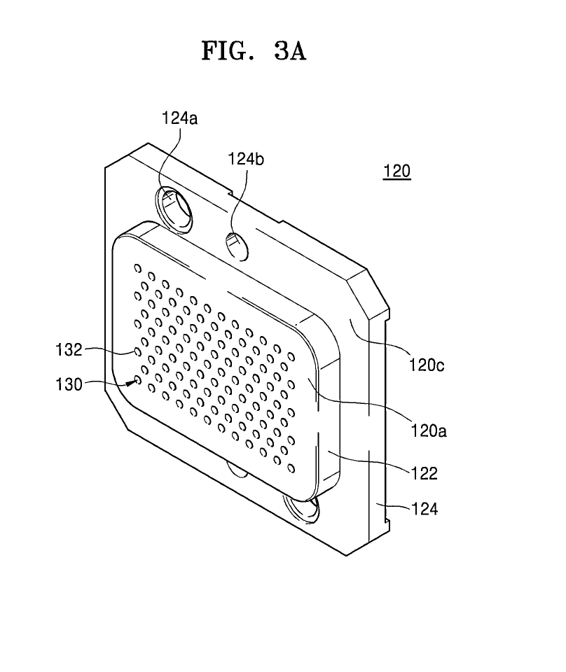

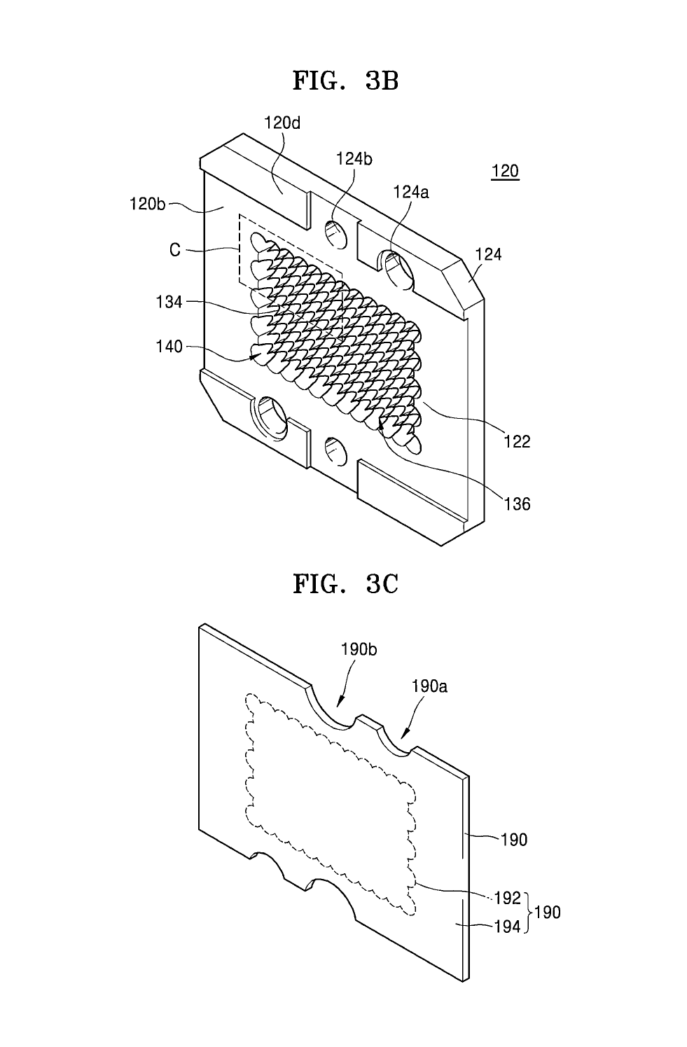

FIGS. 2A and 2B are cross-sectional views of the plasma detecting structure 100 mounted on the chamber 10 according to some example embodiments of the present inventive concepts, and FIGS. 3A through 3C are perspective views of a plasma shielding member and a light transmission member included in the plasma detecting structure 100 of some example embodiments. In particular, FIGS. 3A and 3B are perspective views showing a first surface and a second surface of the plasma shielding member according to some example embodiments, and FIG. 3C is a perspective view of the light transmission member according to some example embodiments.

Referring to FIGS. 2A, and 3A through 3C, the plasma detecting structure 100 may be mounted in the opening 16 of the chamber 10.

The plasma detecting structure 100 includes a plasma shielding member 120 and a light transmission member 190. The plasma detecting structure 100 may have a structure in which the light transmission member 190 is coupled to the plasma shielding member 120.

The plasma shielding member 120 may include a body 122 and a flange 124 surrounding the body 122. The body 122 and the flange 124 may be formed integrally with each other; however, example embodiments of the present inventive concepts are not limited thereto. For example, the body 122 and the flange 124 may be separately formed, and then, may be coupled or attached to each other.

The body 122 includes a first surface 120a and a second surface 120b that are opposite to each other, and a plurality of through holes 130 extending from the first surface 120a to the second surface 120b to penetrate through the body 122. The body 122 may be formed of a metal material, for example, aluminum. An anti-oxidation layer may be formed on the first surface 120a and/or the second surface 120b of the body 122. In addition, an etch stop layer (not shown) may be formed on the first surface 120a of the body 122.

The plasma shielding member 120 may be mounted in the opening 16 so that the first surface 120a faces inside of the chamber 10. The plasma shielding member 120 may be mounted in the opening 16 so that the first surface 120a may not protrude into the chamber 10. The light transmission member 190 may be attached to the second surface 120b of the plasma shielding member 120. The light transmission member 190 may be formed of a material that may transmit the plasma beam, for example, quartz or sapphire. The light transmission member 190 may include a boundary portion 194 contacting the second surface 120b of the plasma shielding member 120 and an intermediate portion 192 separate from the plasma shielding member 120. The intermediate portion 192 and the boundary portion 194 may be formed integrally with each other.

The plasma shielding member 120 does not completely shield the light transmission member 190 from the plasma, but reduces the plasma (plasma beam) transmitted to the light transmission member 190 by transmitting the plasma to the light transmission member 190 via the through holes 130.

The spectrum analyzer 60 or the photocoupler 62 shown in FIGS. 1A and 1B are attached to be adjacent to the light transmission member 190 and, thus, may analyze the plasma beam transmitted through the through holes 130 from the chamber 10. The spectrum analyzer 60 or the photocoupler 62 of FIGS. 1A and 1B may be attached to be opposite to the plasma shielding member 120 while interposing the light transmission member 190 therebetween.

The flange 124 may include a third surface 120c and a fourth surface 120d that are opposite to each other. The third surface 120c and the fourth surface 120d of the flange 124 may be oriented toward the same directions as those of the first surface 120a and the second surface 120b of the body 122, respectively. The flange 124 may include a first coupling hole 124a and a second coupling hole 124b penetrating through the flange 124 from the third surface 120c toward the fourth surface 120d. The first coupling hole 124a is used to engage the flange 124 with the light transmission member 190, and the second coupling hole 124b may be used to engage the flange 124 with the chamber 10 shown in FIGS. 1A and 1B. Cutouts 190a and 190b shown in FIG. 3C may correspond to first and second coupling holes 124a and 124b shown in FIG. 3B.

The body 122 may protrude from the third surface 120c of the flange 124. The part of the body 122 protruding from the third surface 120c of the flange 124 may be inserted into the opening 16 shown in FIGS. 1A and 1B. The plasma shielding member 120 may be attached to the chamber 10 while the third surface 120c of the flange 124 may contact an outer wall of the chamber 10 shown in FIGS. 1A and 1B.

The body 122 may have a depressed shape from the fourth surface 120d of the flange 124. The light transmission member 190 may be attached to contact a surface of the body 122 that is depressed from the fourth surface 120d of the flange 124, that is, the second surface 120b. However, example embodiments of the present inventive concepts are not limited thereto, that is, the fourth surface 120d of the flange 124 may be located at the same level as the second surface 120b of the body 122.

The body 122 may include the plurality of through holes 130. Each of the plurality of through holes 130 may include a narrow portion 132 and a wide portion 134 at opposite ends thereof. The narrow portion 132 and the wide portion 134 may be parts of the body 122 that are adjacent to the through holes 130 to define the through holes 130; however, example embodiments of the present inventive concepts are not limited thereto. The narrow portion 132 and the wide portion 134 may be separate elements that are inserted into opposite ends of each through hole 130 to define widths of the through hole 130. The wide portion 134 is a portion having a width or a cross-sectional area greater than that of the narrow portion 132, and in particular, a width of the through hole 130 defined by the wide portion 134 is greater than a width of the through hole 130 defined by the narrow portion 132 or a cross-sectional area of the through hole 130 defined by the wide portion 134 is greater than a cross-sectional area of the through hole 130 defined by the narrow portion 132.

A part of the body 122 that is adjacent to the through holes 130 so as to surround the entire through holes 130 may be referred to as a through hole portion. That is, the through hole portion may extend from the narrow portion 132 to the wide portion 134, and may be a part of the body 122 surrounding the through holes 130.

A portion of the through hole 130 defined by the narrow portion 132 may have a width and a cross-sectional area that are less than those of a portion of the through hole 130 defined by the wide portion 134. Here, the width and the cross-sectional area of the through hole 130 denote a width and a cross-sectional area of a surface that is perpendicular to the extending direction of the through hole 130, that is, a direction extending from the first surface 120a toward the second surface 120b.

The narrow portion 132 may be formed at an end of the through hole 130, which contacts the first surface 120a, and the wide portion 134 may be formed at an opposite end of the through hole 130. The plasma shielding member 120 may be mounted in the opening 16 of the chamber 10 so that the first surface 120a of the body 122 may face the inside of the chamber 10 shown in FIGS. 1A and 1B. Therefore, the narrow portion 132 is formed at one side of the chamber 10, that is, at a chamber 10 side, and the wide portion 134 may be formed at another side of the chamber 10, that is, at an opposite side of the chamber 10.

Although not shown in drawings, the body 122 at the ends of the through holes 130 may be rounded intentionally or unintentionally during processing of the through holes 130. The narrow portion 132 may be an end of the through hole 130, a part of the body 122 defining the smallest cross-sectional area of the through hole 130, or a part including a rounded part of the body 122. The narrow portion 132 may be formed on the first surface 120a of the body 122, or to be adjacent to the first surface 120a.

Each of the through holes 130 extends from the first surface 120a toward the second surface 120b and, accordingly, the width and the cross-sectional area of the through hole 130 may be increased. At least two wide portions 134 defining at least two adjacent through holes 130 contact each other so that some parts thereof are shared therebetween. A projection 136 may be formed on the wide portion 134 between the at least two adjacent through holes 130.

The width and the cross-sectional area of the through hole 130 may be increased linearly or non-linearly. The width and the cross-sectional area of the through hole 130 may be increased continuously or discontinuously. The through hole 130 may extend from the first surface 120a to the second surface 120b so that the width and the cross-sectional area may be increased at a constant rate or at an increasing rate.

A cross-section of each of the through holes 130 may have a circular shape, a polygonal shape, or a combined shape. The cross-section of the through hole 130 may be formed as a circle, an oval, a rectangular triangle, a right triangle, an isosceles triangle, a square, a rectangle, a rhombus, a trapezoid, a parallelogram, a hexagon, or a combination thereof. The combined shape is obtained by combining the circular shape and the polygonal shape, for example, a part of the cross-section may be partially circular and the other part of the cross-section may be polygonal.

The through holes 130 may be arranged in zig-zags on the cross-section seen from the first surface 120a or the second surface 120b, that is, on a plane parallel with the first surface 120a or the second surface 120b.

The wide portion 134 may be formed on the other end of each of the through holes 130. The wide portion 134 may be a part of the body 122 defining the largest cross-sectional area of the through hole 130, or may be a portion including the above part of the body 122.

The plasma shielding member 120 may include a recessed space 140 that is recessed from the second surface 120b. The recessed space 140 may be a space formed by the through holes 130 that are connected to each other during manufacturing of the through holes 130. Otherwise, the recessed space 140 may be a space formed by removing a part of the body 122 from the second surface 120b of the body 122.

The plasma shielding member 120 or the body 122 is penetrated, from the first surface 120a to the second surface 120b of the body 122, by the connection between the through holes 130 and the recessed space 140. Thus, the through holes 130 and the recessed space 140 may be compatible with each other as first through holes 130 and a second through hole 140. A part of the body 122 adjacent to the first through holes 130 to define the first through holes 130 may be referred to as a first through hole portion. The first through hole portion extends from the narrow portion 132 to the wide portion 134, and may be a part of the body 122 surrounding the first through holes 130. A part of the body 122 adjacent to the second through hole 140 for defining the second through hole 140 may be referred to as a second through hole portion. The intermediate portion 192 of the light transmission member 190 may be separated from the plasma shielding member 120 by the interposing of the second through hole 140 defined by the second through hole portion therebetween.

The recessed space 140 may be connected to all of the plurality of through holes 130. The second through hole portion may be connected to all of the first through hole portions. FIG. 2A shows only one recessed space 140; however, the body 122 may include a plurality of recessed spaces 140 that are respectively connected to the plurality of through holes 130. For example, the body 122 may include one recessed space 140 connected to ‘x’ through holes 130, or may include ‘y’ recessed spaces 140 connected to x×y through holes 130 (‘x’ and ‘y’ are positive integers).

The wide portion 134 may be a part of the body 122 defining each of the through holes 130 at a boundary between the recessed space 140 and the through hole 130. The wide portion 134 may be separated from a plane located at the same level as the second surface 120b by as much as a depth of the recessed space 140. The wide portion 134 may be formed in the body 122 to be separated from the light transmission member 190. The wide portion 134 may be separated from the light transmission member 190 by as much as the depth of the recessed space 140.

Referring to FIG. 2B, the plasma detecting structure 100a may be mounted in the opening 16 of the chamber 10. The plasma detecting structure 100a includes the plasma shielding member 120 and the light transmission member 190.

The plasma shielding member 120 may be mounted in the opening 16 to be protruded into the chamber 10 of the first surface 120a. That is, the plasma shielding member 120 may be mounted in the opening 16 so that the body 122 may protrude from an inner wall of the chamber 10 into the chamber 10.

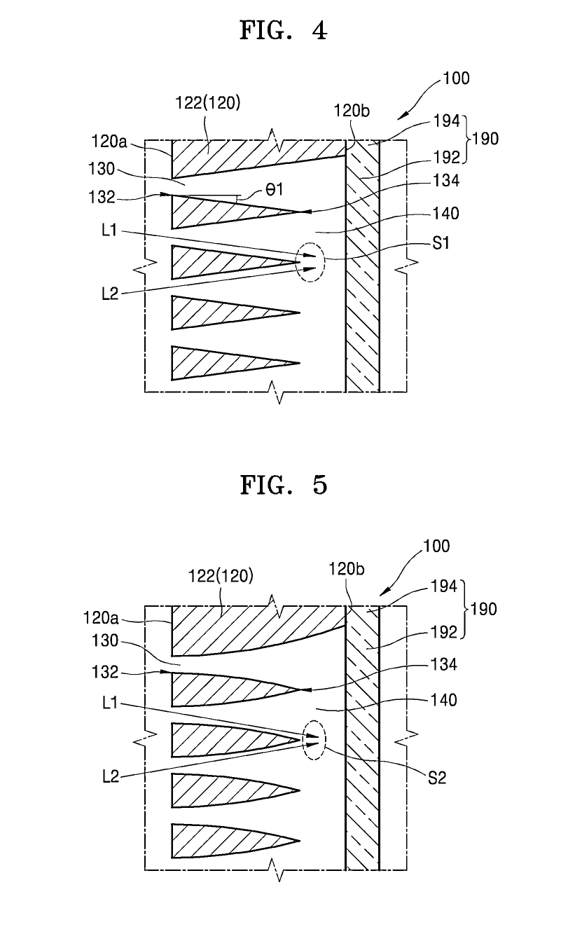

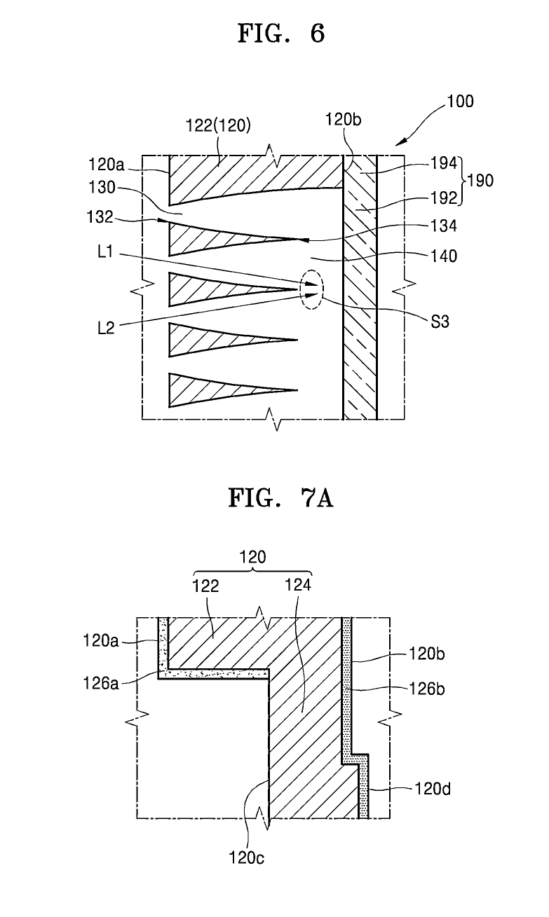

FIGS. 4 through 6 are cross-sectional views showing enlarged parts in the plasma detecting structure according to some example embodiments of the present inventive concepts. FIGS. 4 through 6 show enlarged views of a portion A in FIGS. 2A and 2B, and descriptions about components shown in FIG. 4 may be omitted in descriptions of FIGS. 5 and 6.

Referring to FIG. 4, each of the through holes 130 is formed to extend from the narrow portion 132 to the wide portion 134 while forming an inclined surface. The through hole 130 may be formed so that a cross-section taken along a direction extending from the first surface 120a to the second surface 120b, that is, a cross-section seen from a side surface of the through hole 130, may be formed as an inclined surface straight from the narrow portion 132 to the wide portion 134. An inclined angle 01 of the inclined surface formed by the through hole 130 from the narrow portion 132 to the wide portion 134 may range from 2.5° to 12.5°.

A first through hole portion is a part of the body 122 extending from the narrow portion 132 to the wide portion 134 while surrounding the through hole 130, and a cross-sectional area of a space defined by the first through hole portion increases from the first surface 120a toward the second surface 120b. Also, the first through hole portion may extend so that the cross-sectional area of the space defined by the first through hole portion may linearly increase from the first surface 120a to the second surface 120b.

Plasma beams L1 and L2 passed through at least two adjacent through holes 130 may be mixed in a mixture space Si that is a part of the recessed space 140 that is adjacent to the wide portion 134. That is, the mixture space S1 may be formed between the plasma shielding member 120 and the light transmission member 190. Therefore, the plasma beams L1 and L2 passed through the through holes 130 are mixed in the recessed space 140, and a relatively constant light intensity may be obtained in the recessed space 140. Therefore, the plasma beams L1 and L2 passed through the through holes 130 may reach respective portions of the intermediate portion 192 of the light transmission member 190 exposed by the recessed space 140 with relatively uniform light intensities. Contamination or damage to the light transmission member 190, in particular, the intermediate portion 192, caused by the plasma beams L1 and L2 passed through the through holes 130 may constantly occur on the respective portions of the intermediate portion 192. Therefore, generation of irregular reflection from the light transmission member 190 may be prevented, and the plasma beams L1 and L2 may be precisely sensed and analyzed.

Referring to FIG. 5, the through hole 130 may be formed so that a cross-section taken long a direction extending from the first surface 120a to the second surface 120b, that is, a cross-section seen from a side of the through hole 130, may extend while forming an inclined surface curved from the narrow portion 132 to the wide portion 134. The through hole 130 may extend while forming a convexly inclined surface with respect to the body 122 from the narrow portion 132 to the wide portion 134.

A first through hole portion that is a part of the body 122 extending from the narrow portion 132 to the wide portion 134 and surrounding the through hole 130 may extend from the first surface 120a to the second surface 120b so that a cross-sectional area of the space defined by the first through hole portion may increase non-linearly.

The plasma beams L1 and L2 transmitted through at least two adjacent through holes 130 may be mixed in a mixture space S2 that is a part of the recessed space 140 that is adjacent to the wide portion 134. Therefore, the plasma beams L1 and L2 transmitted through the through holes 130 are mixed in the recessed space 140 so as to have relatively uniform light intensities in the recessed space 140. The plasma beams L1 and L2 transmitted through the through holes 130 may spread widely in the recessed space 140 due to the convexly inclined surface. Therefore, the plasma beams L1 and L2 transmitted through the through holes 130 may reach respective portions on the intermediate portion 192 of the light transmission member, which is exposed by the recessed space 140, with relatively uniform light intensities.

FIG. 6 is a cross-sectional view showing a partially enlarged part of the plasma detecting structure according to some example embodiments of the present inventive concepts. The through holes 130 are formed to extend from the narrow portion 132 to the wide portion 134 while forming inclined surfaces. Each of the through holes 130 may be configured so that a cross-section taken along a direction extending from the first surface 120a to the second surface 120b, that is, the cross-section seen from the side of the through hole 130, may extend from the narrow portion 132 to the wide portion 134 while forming an inclined surface that is curved. The through hole 130 may extend while forming a concavely inclined surface with respect to the body 122 from the narrow portion 132 to the wide portion 134.

The plasma beams L1 and L2 transmitted through at least two adjacent through holes 130 may be mixed in a mixture space S3 that is a part of the recessed space 140 that is adjacent to the wide portion 134. Therefore, the plasma beams L1 and L2 transmitted through the through holes 130 are mixed in the recessed space 140 so as to have relatively uniform light intensities in the recessed space 140. Since the cross-sectional area of the through hole 130 increases non-linearly while the through hole 130 extends from the first surface 120a to the second surface 120b, the plasma beams L1 and L2 may be uniformly dispersed in the recessed space 140. Therefore, the plasma beams L1 and L2 transmitted through the through holes 130 may reach respective portions on the intermediate portion 192 of the light transmission member, which is exposed by the recessed space 140, with relatively uniform light intensities.

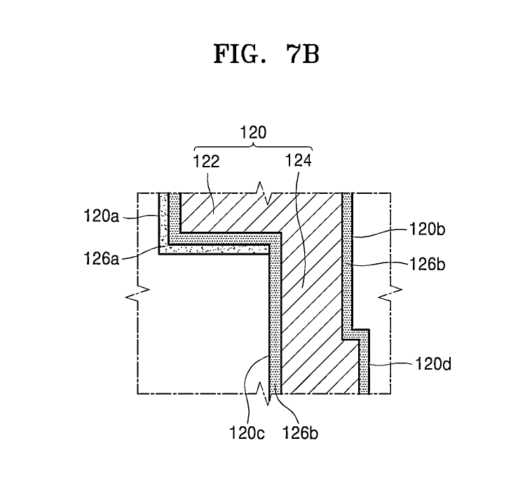

FIGS. 7A and 7B are cross-sectional views partially enlarging some parts of the plasma shielding member 120 according to some example embodiments of the present inventive concepts. In particular, FIGS. 7A and 7B show enlarged views of a portion B of the plasma shielding member 120 shown in FIGS. 2A and 2B.

Referring to FIG. 7A, an etch stop layer 126a may be formed on the first surface 120a of the plasma shielding member 120. An anti-oxidation layer 126b may be formed on the second surface 120b of the plasma shielding member 120.

The etch stop layer 126a may be formed on the entire surface of the body 122 that protrudes from the third surface 120c of the flange 124. That is, the etch stop layer 126a may be formed on the first surface 120a, and on the side surfaces of the body 122 between the first surface 120a and the third surface 120c. The etch stop layer 126a may be formed to prevent damage to the body 122 due to the plasma beams in the chamber 10 shown in FIGS. 1A and 1B. The etch stop layer 126a may include, for example, Y₂O₃, Sc₂O₃, Sc₂F₃, YF₃, La₂O₃, CeO₂, Eu₂O₃, or DyO₃.

The anti-oxidation layer 126b may be formed to extend from the second surface 120b of the body 122 to the fourth surface 120d of the flange 124. That is, the anti-oxidation layer 126b may be formed to cover the entire surface that is opposite to the first surface 120a of the plasma shielding member 120.

The anti-oxidation layer 126b may be formed by, for example, anodizing and oxidizing an exposed surface of the plasma shielding member 120. The anti-oxidation layer 126b may be, for example, aluminum oxide layer.

FIG. 7A shows the etch stop layer 126a and the anti-oxidation layer 126b only on portions on which etching and oxidation need to be prevented, and example embodiments of the present inventive concepts are not limited thereto.

Referring to FIG. 7B, the etch stop layer 126a may be formed on the first surface 120a of the plasma shielding member 120. The anti-oxidation layer 126b may be formed on the second surface 120b of the plasma shielding member 120. The anti-oxidation layer 126b may be formed with the etch stop layer 126a along a lower portion of the etch stop layer 126a. Also, the anti-oxidation layer 126b may be formed on the third surface 120c of the flange 124. For example, the anti-oxidation layer 126b may be formed to cover the entire exposed surface of the plasma shielding member 120, and the etch stop layer 126a may be formed to cover the anti-oxidation layer 126b formed on the surface of the body 122 protruding from the third surface 120c.

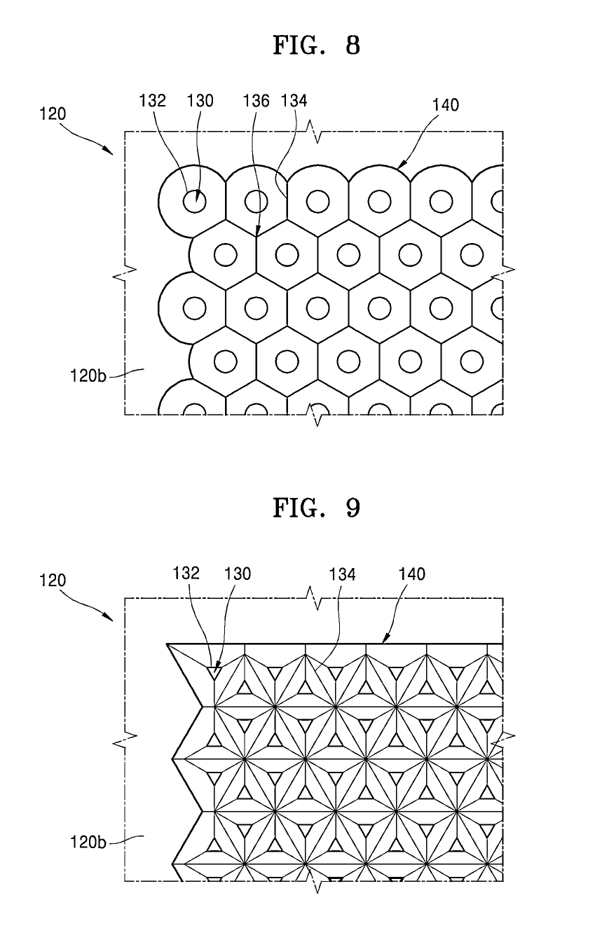

FIGS. 8 through 11 are plan views showing enlarged parts of the plasma shielding member 120 according to some example embodiments of the present inventive concepts, and in particular, a portion C shown in FIG. 3B. In addition, descriptions about the components that are described with reference to FIG. 8 may be omitted here.

Referring to FIG. 8, each through hole 130 may extend from the narrow portion 132 to the wide portion 134 as the width and cross-sectional area of the through hole 130 increases. The plurality of through holes 130 may be arranged in zig-zags with respect to a direction (for example, a transverse direction or a longitudinal direction of FIG. 8). The plurality of through holes 130 may be connected to the recessed space 140. At least two wide portions 134 defining at least two adjacent through holes 130 may contact each other so that some parts thereof are shared therebetween. The projection 136 may be formed between the wide portions 134 of the at least two adjacent through holes 130. Each of the through holes 130 may have a circular cross-section. The cross-section of the through hole 130 may have a circular shape or an oval shape. When the plurality of through holes 130 have circular cross-sections that are arranged in zig-zags, a part of the cross-section of the through hole 130, which contacts the other through holes 130, may be a part of the circle and the other part of the cross-section of the through hole 130 may be a part of a polygon. A cross-section of the portion defined by the narrow portion 132 formed at an end of the through hole 130 may be circular, and a cross-section of the portion defined by the wide portion 134 formed at the other end of the through hole 130 may have a combined shape. The narrow portion 132 may be formed on the first surface 120a shown in FIG. 3B, that is, a plane; however, the wide portion 134 may have curved shapes as shown in FIG. 3B. According to the contacts between the through holes 130 that extend while increasing in cross-sectional area, the wide portions 134 may have the curved shapes.

The recessed space 140 may have edges defined along portions where a virtual space extending from the plurality of through holes 130 contacts the second surface 120b. Therefore, the edges of the recessed space 140 may have a shape obtained by combining arcs of the circular shapes.

Referring to FIG. 9, the through holes 130 may extend while the widths and the cross-sectional areas thereof increase from the narrow portion 132 to the wide portion 134. The plurality of through holes 130 may be connected to the recessed space 140. At least two wide portions 134 defining at least two adjacent through holes 130 contact each other and share some parts thereof with each other. A cross-section of each of the through holes 130 may be a triangle. The cross-section of each through hole 130 may be formed as a regular triangle, a right-angled triangle, or an isosceles triangle. A cross-section of the portion defined by the narrow portion 132 formed at an end of the each through hole 130 may be formed as a triangle, and a cross-section of the portion defined by the wide portion 134 formed at the other end of the through hole 130 may be formed as a triangle.

The recessed space 140 may have edges defined along portions where a virtual space extending from the plurality of through holes 130 contacts the second surface 120b. Therefore, the edges of the recessed space 140 may have a shape obtained by combining edges of the triangles.

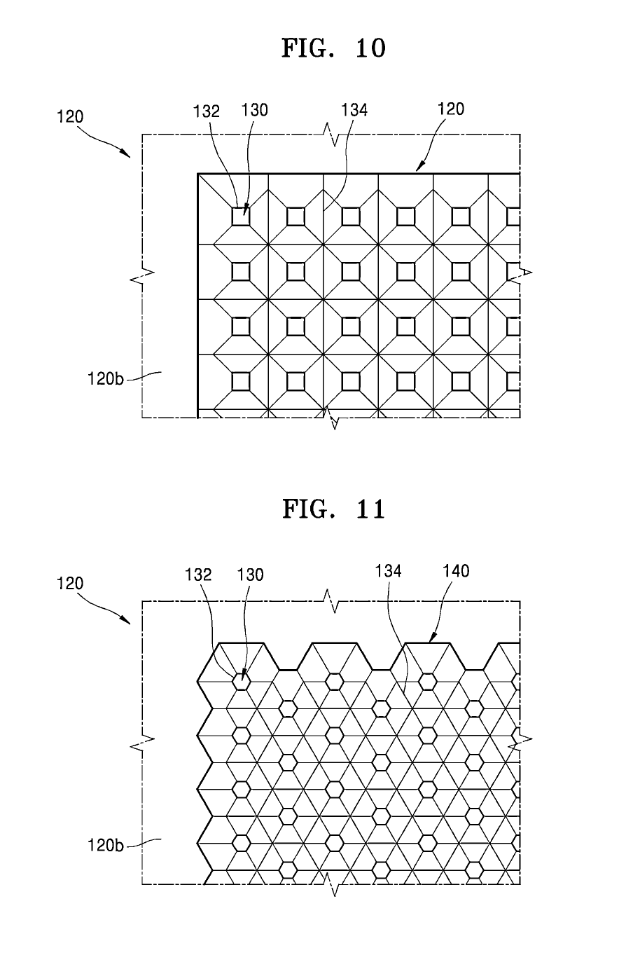

Referring to FIG. 10, the through holes 130 may extend while the widths and the cross-sectional areas thereof increase from the narrow portion 132 to the wide portion 134. The plurality of through holes 130 may be connected to the recessed space 140. At least two wide portions 134 defining at least two adjacent through holes 130 contact each other and share some parts with each other. A cross-section of each of the through holes 130 may be a quadrangle shape, for example, a square, a rectangle or a rhombus, or a trapezoid. A cross-section of the portion defined by the narrow portion 132 formed at an end of the each through hole 130 may be formed as a quadrangle, and a cross-section of the portion defined by the wide portion 134 formed at the other end of the through hole 130 may be formed as a quadrangle.

The recessed space 140 may have edges defined along portions where a virtual space extending from the plurality of through holes 130 contacts the second surface 120b. Therefore, the edges of the recessed space 140 may have a shape obtained by combining edges of the quadrangles.

Referring to FIG. 11, the through holes 130 may extend while the widths and the cross-sectional areas thereof increase from the narrow portion 132 to the wide portion 134. The plurality of through holes 130 may be arranged in zig-zags with respect to a direction (for example, a horizontal direction or a vertical direction in FIG. 11). The plurality of through holes 130 may be connected to the recessed space 140. At least two wide portions 134 defining at least two adjacent through holes 130 contact each other and share some parts with each other. Each of the through holes 130 may have a hexagonal cross-section. The plurality of through holes 130 may be arranged as a honeycomb shape, in which hexagonal cross-sections are arranged in zig-zags with respect to a direction. A cross-section of the portion defined by the narrow portion 132 formed at an end of the each through hole 130 may be formed as a hexagon, and a cross-section of the portion defined by the wide portion 134 formed at the other end of the through hole 130 may be formed as a hexagon.

The recessed space 140 may have edges defined along portions where a virtual space extending from the plurality of through holes 130 contacts the second surface 120b. Therefore, the edges of the recessed space 140 may have a shape obtained by combining edges of the hexagons.

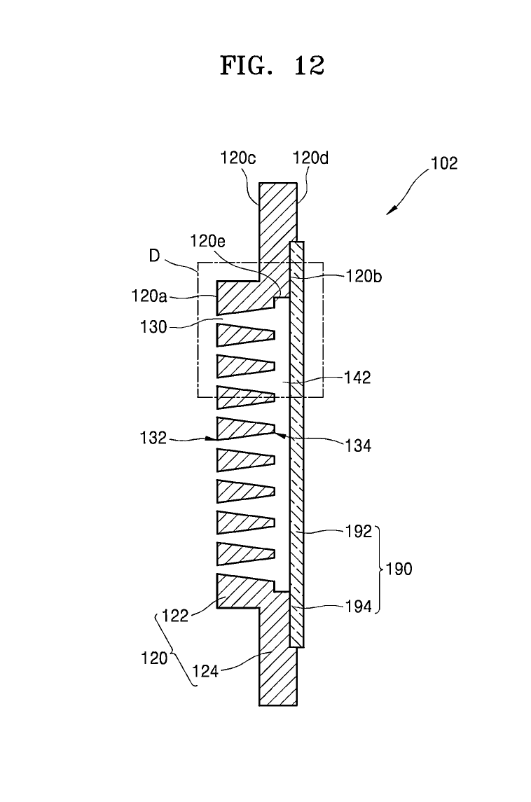

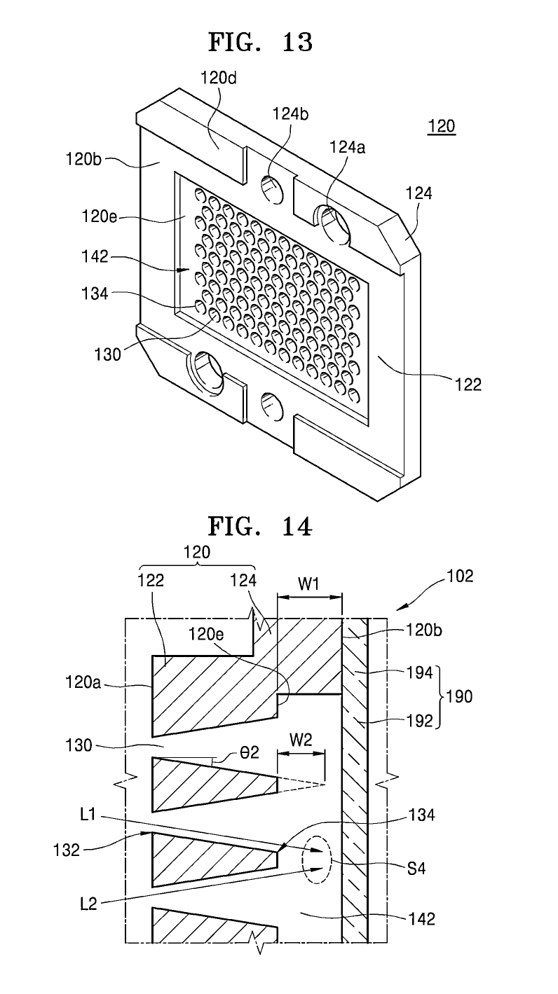

FIG. 12 is a cross-sectional view of a plasma detecting structure 102 according to some example embodiments of the present inventive concepts, and FIG. 13 is a perspective view of a plasma shielding member included in the plasma detecting structure 102 according to some example embodiments of the present inventive concepts. In particular, FIG. 13 is a perspective view showing a second surface of the plasma shielding member according to some example embodiments. A perspective view showing a first surface of the plasma shielding member is already shown in FIG. 3A and, thus, is omitted here. In addition, descriptions that are the same as those of FIGS. 2A through 3C are not provided here.

Referring to FIGS. 12 and 13, the plasma detecting structure 102 includes the plasma shielding member 120 and the light transmission member 190. The plasma detecting structure 102 may have a structure in which the light transmission member 190 is coupled to the plasma shielding member 120. The plasma shielding member 120 may include the body 122 and the flange 124 surrounding the body 122. The body 122 and the flange 124 may be formed integrally with each other; however, example embodiments are not limited thereto. For example, the body 122 and the flange 124 may be separately formed and then coupled or attached to each other.

The body 122 includes the first surface 120a and the second surface 120b that are opposite to each other, and the plurality of through holes 130 extending from the first surface 120a to the second surface 120b may penetrate through the body 122. The body 122 may be formed of metal, for example, aluminum. An anti-oxidation layer may be formed on the first surface 120a and/or the second surface 120b of the body 122. In addition, an etch stop layer may be formed on the first surface 120a of the body 122.

The plasma shielding member 120 may be mounted in the opening 16 so that the first surface 120a may face the inside of the chamber 10 shown in FIGS. 1A and 1B. The light transmission member 190 may be attached to the second surface 120b of the plasma shielding member 120. The light transmission member 190 may be formed of a material transmitting the plasma beam, for example, the light transmission member 190 may be formed of quartz or sapphire. The light transmission member 190 includes the boundary portion 194 contacting the second surface 120b of the plasma shielding member 120 and the intermediate portion 192 that is separated from the plasma shielding member 120. The intermediate portion 192 and the boundary portion 194 may be formed integrally with each other.

The flange 124 may include the third surface 120c and the fourth surface 120d that are opposite to each other. The third and fourth surfaces 120c and 120d of the flange 124 may be surfaces respectively facing the first and second surfaces 120a and 120b of the body 122. The flange 124 is penetrated, from the third surface 120c toward the fourth surface 120d, by the formation of the first coupling hole 124a and the second coupling hole 124b in the flange 124. The first coupling hole 124a is used to engage the flange 124 with the light transmission member 190, and the second coupling hole 124b may be used to engage the flange 124 with the chamber 10 shown in FIGS. 1A and 1B.

The body 122 may protrude from the third surface 120c of the flange 124. The part of the body 122 protruding from the third surface 120c of the flange 124 may be inserted into the opening 16 shown in FIGS. 1A and 1B. The plasma shielding member 120 may be attached to the chamber 10 while the third surface 120c of the flange 124 may contact an outer wall of the chamber 10 shown in FIGS. 1A and 1B.

The body 122 may have a depressed shape from the fourth surface 120d of the flange 124. The light transmission member 190 may be attached to contact a surface of the body 122 that is depressed from the fourth surface 120d of the flange 124, that is, the second surface 120b. However, example embodiments of the present inventive concepts are not limited thereto, that is, the fourth surface 120d of the flange 124 may be located at the same level as the second surface 120b of the body 122.

The body 122 may include the plurality of through holes 130. Each of the plurality of through holes 130 may include a narrow portion 132 and a wide portion 134 at opposite sides thereof. The narrow portion 132 and the wide portion 134 may be parts of the body 122 that are adjacent to the through holes 130 to define the through holes 130; however, example embodiments of the present inventive concepts are not limited thereto. The narrow portion 132 and the wide portion 134 may be separate elements that are inserted into opposite ends of each through hole 130 to define widths of the through hole 130.

A part of the body 122 that is adjacent to the through holes 130 so as to surround all of the through holes 130 may be referred to as a through hole portion. That is, the through hole portion may extend from the narrow portion 132 to the wide portion 134, and may be a part of the body 122 surrounding the through holes 130.

A portion of the through hole 130 defined by the narrow portion 132 may have a width and a cross-sectional area that are less than those of a portion of the through hole 130 defined by the wide portion 134. Here, the width and the cross-sectional area of the through hole 130 denote a width and a cross-sectional area of a surface that is perpendicular to the extending direction of the through hole 130, that is, a direction extending from the first surface 120a toward the second surface 120b.

The narrow portion 132 may be formed at an end of the through hole 130, which contacts the first surface 120a, and the wide portion 134 may be formed at an opposite end of the through hole 130. The plasma shielding member 120 may be mounted in the opening 16 of the chamber 10 so that the first surface 120a of the body 122 may face the inside of the chamber 10 shown in FIGS. 1A and 1B. Therefore, the narrow portion 132 is formed at one side of the chamber 10, that is, at a chamber 10 side, and the wide portion 134 may be formed at another side of the chamber 10, that is, at an opposite side of the chamber 10.

Although not shown in drawings, the body 122 at the ends of the through holes 130 may be rounded intentionally or unintentionally during processing of the through holes 130. The narrow portion 132 may be an end of the through hole 130, a part of the body 122 defining the smallest cross-sectional area of the through hole 130, or a part including a rounded part of the body 122. The narrow portion 132 may be formed on the first surface 120a of the body 122, or to be adjacent to the first surface 120a.

Each of the through holes 130 extends from the first surface 120a toward the second surface 120b, and accordingly, the width and the cross-sectional area of the through hole 130 may be increased. The width and the cross-sectional area of the through hole 130 may be increased linearly or non-linearly, and continuously or discontinuously. Each of the through holes 130 may extend from the first surface 120a to the second surface 120b so that the width and the cross-sectional area thereof may increase at a constant ratio or at an increasing ratio.

Although FIGS. 12 and 13 show the through holes 130 having circular cross-sections, the cross-sections of the through holes 130 may have circular shapes, polygonal shapes, or combined shapes as shown in FIGS. 8 through 11, for example, circular shapes, oval shapes, rectangular triangles, right triangles, isosceles triangles, squares, rectangles, rhombuses, trapezoids, parallelograms, hexagons, or combined shapes thereof. The combined shape may have a shape, such that, a part of the cross-section may be partially circular and the other part of the cross-section may be polygonal.

The through holes 130 may be arranged in zig-zags on the cross-section seen from the first surface 120a or the second surface 120b, that is, on a plane parallel with the first surface 120a or the second surface 120b.

The wide portion 134 may be formed on the other end of each of the through holes 130. The wide portion 134 may be a part of the body 122 defining the largest cross-sectional area of the through hole 130, or may be a portion including the above part of the body 122.

The plasma shielding member 120 may include a recessed space 142 that is recessed from the second surface 120b. The recessed space 142 may be a space formed by removing a part of the body 122 from the second surface 120b of the body 122.

The plasma shielding member 120 or the body 122 is penetrated, from the first surface 120a to the second surface 120b of the body 122, by the connection between the through holes 130 and the recessed space 142. Thus, the through holes 130 and the recessed space 142 may be compatible with each other as first through holes 130 and a second through hole 142. A part of the body 122 adjacent to the first through holes 130 to define the first through holes 130 may be referred to as a first through hole portion. The first through hole portion extends from the narrow portion 132 to the wide portion 134, and may be a part of the body 122 surrounding the first through holes 130. A part of the body 122 adjacent to the second through hole 142 for defining the second through hole 142 may be referred to as a second through hole portion. The intermediate portion 192 of the light transmission member 190 may be separated from the plasma shielding member 120 by the interposing of the second through hole 142 defined by the second through hole portion therebetween.

The recessed space 142 may be connected to all of the plurality of through holes 130. The second through hole portion may be connected to all of the first through hole portions. FIGS. 12 and 13 show only one recessed space 142; however, the body 122 may include a plurality of recessed spaces 142 that are respectively connected to the plurality of through holes 130. For example, the body 122 may include one recessed space 142 connected to ‘x’ through holes 130, or may include ‘y’ recessed spaces 142 connected to x×y through holes 130 (‘x’ and ‘y’ are positive integers).

The wide portion 134 may be a part of the body 122 defining each of the through holes 130 at a boundary between the recessed space 142 and the through hole 130. The wide portion 134 may be separated from a plane located at the same level as the second surface 120b by as much as a depth of the recessed space 142. The wide portion 134 may be formed in the body 122 to be separated from the light transmission member 190. The wide portion 134 may be separated from the light transmission member 190 by as much as the depth of the recessed space 142.

Unlike the plasma detecting structure 100 shown in FIGS. 2A through 3C, according to the plasma detecting structure 102 shown in FIGS. 12 and 13, the wide portions 134 defining the adjacent through holes 130 may not contact each other. The wide portions 134 may be formed in a plane that is in parallel with the second surface 120b. The wide portions 134 may be formed on a fifth surface 120e that is apart a distance (that may or may not be predetermined) from the recessed space 142.

FIG. 14 is a cross-sectional view showing an enlarged part of the plasma detecting structure 102 according to some example embodiments, in particular, a portion D shown in FIG. 12.

Referring to FIG. 14, each of the through holes 130 is formed to extend from the narrow portion 132 to the wide portion 134 while forming an inclined surface. The through hole 130 may be formed so that a cross-section taken along a direction extending from the first surface 120a to the second surface 120b, that is, a cross-section seen from a side surface of the through hole 130, may be formed as an inclined surface straight from the narrow portion 132 to the wide portion 134. An inclination angle θ2 of the inclined surface formed by the through hole 130 from the narrow portion 132 to the wide portion 134 may range from 2.5° to 12.5°.

The first through hole portion is a part of the body 122 extending from the narrow portion 132 to the wide portion 134 while surrounding the through hole 130, and a cross-sectional area of a space defined by the first through hole portion increases from the first surface 120a toward the second surface 120b. Also, the first through hole portion may extend so that the cross-sectional area of the space defined by the first through hole portion may linearly increase from the first surface 120a to the second surface 120b.

Although not shown in the drawings, the through holes 130 of the plasma detecting structure 102 may extend from the narrow portions 132 to the wide portions 134 while forming convexly or concavely inclined surfaces with respect to the body 122, similarly to FIGS. 5 and 6. That is, the cross-sectional area of the space defined by the first through hole portion may extend while increasing non-linearly.

Plasma beams L1 and L2 passed through at least two adjacent through holes 130 may be mixed in a mixture space S4 that is a part of the recessed space 142 that is adjacent to the wide portion 134. Therefore, the plasma beams L1 and L2 passed through the through holes 130 are mixed in the recessed space 142, and a relatively constant light intensity may be obtained in the recessed space 142. Therefore, the plasma beams L1 and L2 passed through the through holes 130 may reach respective portions of the intermediate portion 192 of the light transmission member 190 exposed by the recessed space 142 with relatively uniform light intensities. Contamination or damage to the light transmission member 190, in particular, the intermediate portion 192, caused by the plasma beams L1 and L2 passed through the through holes 130 may constantly occur on the respective portions of the intermediate portion 192. Therefore, generation of irregular reflection from the light transmission member 190 may be prevented, and the plasma beams L1 and L2 may be precisely sensed and analyzed.

A width of the recessed space 142 may be a first width W1 that is a distance from the second surface 120b to the fifth surface 120e. The through holes 130 are formed to extend while forming the inclined surfaces from the narrow portions 132 to the wide portions 134. Therefore, when the inclined surfaces are virtually extended, virtual inclined surfaces extending from adjacent through holes 130 may contact each other. Here, a distance from the fifth surface 120e to a point where the virtual inclined surfaces contact each other may be a second width W2. The first width W1 may be greater than the second width W2. Therefore, the plasma beams L1 and L2 passed through the at least two adjacent through holes 130 may be mixed with each other in the mixture space S4 that is a part of the recessed space 142.

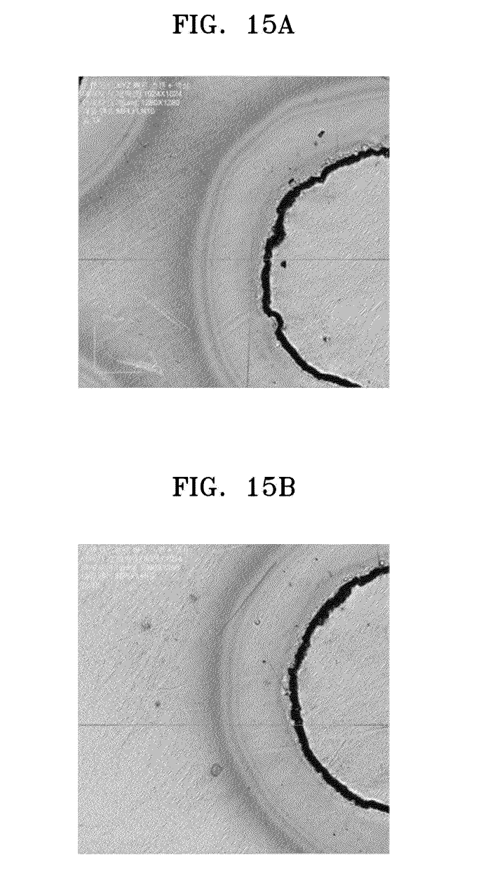

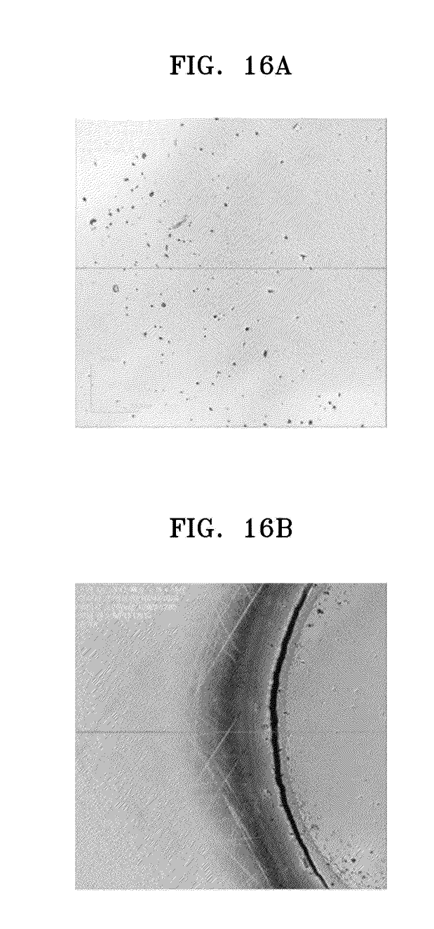

FIGS. 15A and 15B are images of a light transmission member included in a general plasma detecting structure, and FIGS. 16A and 16B are images of a light transmission member included in the plasma detecting structure according to some example embodiments. In particular, FIGS. 15A and 16A show a part of the intermediate portion 192 of the light transmission member 190 shown in FIG. 3C, which is relatively far from the boundary portion 194, for example, a middle portion of the intermediate portion 192, and FIGS. 15B and 16B show a part of the intermediate portion 192, which is relatively close to the boundary portion 194, for example, an edge portion of the intermediate portion 192.

Referring to FIGS. 15A through 16B, it is observed that the light transmission member included in the general plasma detecting structure has damaged portions at a center (FIG. 15A) and an edge (FIG. 15B). However, the light transmission member included in the plasma detecting structure according to some example embodiments of the present inventive concepts does not have a damaged portion at a center thereof (FIG. 16A), but has a damaged portion at an edge thereof (FIG. 16B).

According to the light transmission member included in the general plasma detecting structure, the plasma beams passed through the through holes may only reach corresponding portions of the light transmission member, and damages to the light transmission member which correspond to the plurality of through holes may be observed. Thus, the light transmission member is unevenly damaged. In addition, the plasma beam transmitted though the light transmission member to a spectrum analyzer may be distorted due to the irregular reflection.

However, in the light transmission member 190 included in the plasma detecting structure according to some example embodiments of the present inventive concepts, the plasma beams transmitted through the through holes are mixed to reach the respective portions of the intermediate portion 192 of the light transmission member 190 with uniform light intensities. Thus, the center portion of the intermediate portion 192 may be evenly damaged, that is, evenly worn away, and actually shows the same effects as those when it the center portion is not damaged. Therefore, the plasma beam transmitted to the spectrum analyzer 60 after passing through the light transmission member 190 may not be distorted.

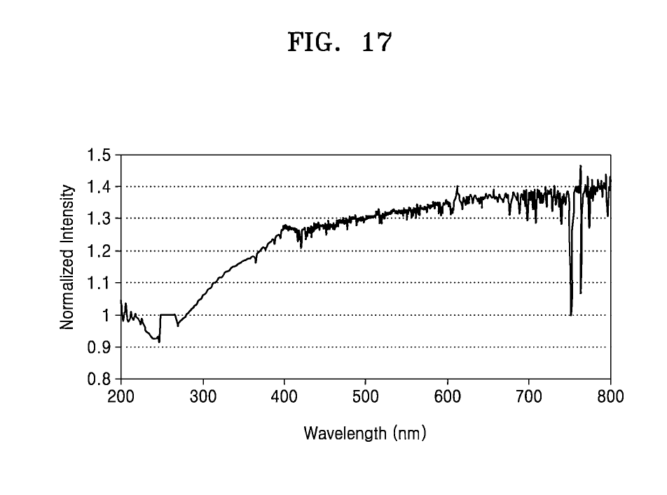

FIG. 17 is a graph showing relative plasma beam detecting efficiency in a plasma reaction apparatus using the plasma detecting structure according to some example embodiments of the present inventive concepts.

Referring to FIG. 17, the plasma beam detecting efficiency of the plasma reaction apparatus using the plasma detecting structure according to some example embodiments increases when a wavelength increases. The plasma reaction apparatus using the general plasma detecting structure may only receive the plasma beams generated from a center of plasma; however, the plasma reaction apparatus using the plasma detecting structure according to some example embodiments of the present inventive concepts may receive plasma beams generated from portions other than the center of the plasma because the through holes extend while forming the inclined surfaces.

An electron temperature of the plasma is distributed spatially and, thus, an electron temperature at the center of the plasma is lower than that at the edge portions of the plasma. Therefore, the plasma beam generated from the center of the plasma may have a relatively short wavelength compared to those generated from the edges. For example, the plasma beam generated from the center of the plasma may have a short wavelength of about 250 nanometers (nm) to about 350 nm. The plasma detecting efficiency of the plasma reaction apparatus according to some example embodiments is not different from that of a general plasma reaction apparatus, with respect to the plasma beam having the short wavelength (in particular, if the plasma beam has a wavelength of about 250 nm to about 275 nm, the light intensity is so strong that a light intensity limitation of the spectrum analyzer is exceeded and, thus, the efficiency rarely changes). However, the plasma detecting efficiency with respect to the plasma beam having a long wavelength is largely increased. Therefore, the spectrum analyzing of the plasma beam of wide range of wavelength band may be performed and, thus, a precise process monitoring or a precise end point detection (EPD) may be performed.

While the inventive concepts have been particularly shown and described with reference to some example embodiments thereof, it will be understood that various changes in form and details may be made therein without departing from the spirit and scope of the following claims.

It should be understood that example embodiments described herein should be considered in a descriptive sense only and not for purposes of limitation. Descriptions of features or aspects within example embodiments should typically be considered as available for other similar features or aspects in other example embodiments.

1. A plasma shielding member, comprising:
a body having a first surface and a second surface that are opposite to each other, and a plurality of through holes each extending from the first surface to the second surface;
a narrower portion of a respective through hole formed at one end of each of the plurality of through holes; and
a wider portion of the respective through hole formed at another end of each of the plurality of through holes.

2. The plasma shielding member of claim 1, wherein the narrower portion of the respective through hole is formed in the first surface of the body, and
wherein the second surface of the body is configured to receive a light transmission member that transmits plasma beams passed through the plurality of through holes.

3. The plasma shielding member of claim I, wherein each of the plurality of through holes extends from the narrower portion of the respective through hole to the wider portion of the respective through hole while forming an inclined surface.

4. The plasma shielding member of claim 3, wherein each of the plurality of through holes has a cross-section which, when seen from a side surface of the respective through hole, forms an inclined surface straight from the narrower portion of the respective through hole to the wider portion of the respective through hole.

5. The plasma shielding member of claim 3, wherein each of the plurality of through holes has a cross-section which, when seen from a side surface of the respective through hole, forms an inclined surface curved from the narrower portion of the respective through hole to the wider portion of the respective through hole.

6. The plasma shielding member of claim 5, wherein each of the plurality of through holes extends from the narrower portion of the respective through hole to the wider portion of the respective through hole while forming a concavely inclined surface or a convexly inclined surface.

7. The plasma shielding member of claim 1, wherein each of the plurality of through holes has a cross-section which, when seen from the first surface or the second surface, has a circular shape, a polygonal shape, or a combined shape of the circular and polygonal shapes.

8. The plasma shielding member of claim 1, wherein the body includes a recessed space that is depressed from the second surface, and
wherein the recessed space is connected to the plurality of through holes.

9. The plasma shielding member of claim 1, wherein the plurality of through holes are arranged in zig-zags with respect to a direction on a plane that is parallel to the first surface.

10. The plasma shielding member of claim 1, wherein a mixture space, in which plasma beams transmitted through at least two adjacent through holes among the plurality of through holes are mixed, is formed to be adjacent to the wider portions of the at least two adjacent through holes.

11. The plasma shielding member of claim 1, further comprising:
a projection at a location between the wider portions of the respective through holes of at least two adjacent through holes among the plurality of through holes.

12. The plasma shielding member of claim 1, wherein the body has an etch stop layer on the first surface.

13. The plasma shielding member of claim 12, wherein the etch stop layer comprises Y₂O₃, Sc₂O₃, Sc₂F₃, YF₃, La₂O₃, CeO₂, Eu₂O₃, or DyO₃.

14. The plasma shielding member of claim 1, wherein the body has an anti-oxidation layer on the second surface.

15-25. (canceled)

26. A plasma shielding member, comprising:
a body including a plurality of through holes that extends from a first surface of the body toward a second surface of the body;
wherein each of the plurality of through holes is defined by a narrower portion of the body at a first end of the respective through hole, and by a wider portion of the body at a second end of the respective through hole.

27. The plasma shielding member of claim 26, wherein each of the plurality of through holes extends from the narrower portion of the body to the wider portion of the body while forming a straight inclined surface,

28. The plasma shielding member of claim 26, wherein each of the plurality of through holes extends from the narrower portion of the body to the wider portion of the body while forming a curved inclined surface.

29. The plasma shielding member of claim 26, wherein the body includes a recessed space that extends from the plurality of through holes to the second surface of the body.

30. The plasma shielding member of claim 26, wherein a mixture space, in which plasma beams transmitted through at least two adjacent through holes among the plurality of through holes are mixed, is formed adjacent to respective wider portions of the body.

31. The plasma shielding member of claim 26, wherein a mixture space, in which plasma beams transmitted through at least two adjacent through holes among the plurality of through holes are mixed, is formed between respective wider portions of the body and the second surface of the body.
